(19) United States
(12) Patent Application Publication
(10) Pub. No.: US 2026/0303031 A1
(43) Pub. Date: Oct. 1, 2026

(54) DIFFERENTIAL POWER AMPLIFIER

(71) Applicant: Murata Manufacturing Co., Ltd., Nagaokakyo-shi (JP)

(72) Inventors: Yuito SAWAYAMA, Nagaokakyo-shi (JP); Tomoya ODA, Nagaokakyo-shi (JP)

(21) Appl. No.: 19/578,991

(22) Filed: Mar. 26, 2026

(30) Foreign Application Priority Data
Mar. 28, 2025 (JP) 2025-056838

(51) Int. Cl. H03F 1/26; H03F 3/191; H03F 3/68

(52) U.S. Cl. CPC H03F 1/26; H03F 3/191; H03F 3/68; H03F 2200/171

(57) ABSTRACT

A differential power amplifier includes: a plurality of differential amplifier circuits including a first differential amplifier circuit and a second differential amplifier circuit; a first inductor having one end connected to an output terminal of the first differential amplifier circuit; a first output terminal connected to another end of the first inductor; a capacitor and a second inductor connected in series between the first output terminal and a ground potential; a second output terminal connected to an output terminal of the second differential amplifier circuit; and a switch circuit provided between the output terminal of the first differential amplifier circuit and the output terminal of the second differential amplifier circuit.

### CROSS REFERENCE TO RELATED APPLICATION

This application claims priority from Japanese Patent Application No. 2025-056838, filed on Mar. 28, 2025. The content of this application is incorporated herein by reference in its entirety.

### BACKGROUND OF THE DISCLOSURE

### 1. Field of the Disclosure

The present disclosure relates to a differential power amplifier.

### 2. Description of the Related Art

In mobile communication fields, such as mobile phones, power amplifier circuits are disclosed in which a plurality of differential amplifier circuits are combined. Japanese Unexamined Patent Application Publication No. 2010-141673 discloses the achievement of broadband frequency characteristics by combining outputs of a plurality of differential amplifier circuits.

### BRIEF SUMMARY OF THE DISCLOSURE

Japanese Unexamined Patent Application Publication No. 2010-141673 does not disclose a configuration for attenuating a harmonic component in differential amplification. Furthermore, in a case where multiple bands are supported, it is better to optimize the bandpass characteristics for each band.

In view of the above, the present disclosure has been made to provide a differential power amplifier that enables optimization of bandpass characteristics for each band by using a plurality of differential amplifier circuits.

A differential power amplifier according to an aspect of the present disclosure includes: a plurality of differential amplifier circuits including a first differential amplifier circuit and a second differential amplifier circuit; a first inductor having one end connected to an output terminal of the first differential amplifier circuit; a first output terminal connected to another end of the first inductor; a capacitor and a second inductor connected in series between the first output terminal and a ground potential; a second output terminal connected to an output terminal of the second differential amplifier circuit; and a switch circuit. The differential power amplifier has a first mode in which the first differential amplifier circuit performs amplification operation and the second differential amplifier circuit does not perform amplification operation and a second mode in which both the first differential amplifier circuit and the second differential amplifier circuit perform amplification operation. The switch circuit is configured to disconnect the output terminal of the first differential amplifier circuit and the output terminal of the second differential amplifier circuit in the first mode and is configured to connect the output terminal of the first differential amplifier circuit and the output terminal of the second differential amplifier circuit in the second mode.

The present disclosure can provide the differential power amplifier that enables optimization of bandpass characteristics for each band by using the plurality of differential amplifier circuits.

### BRIEF DESCRIPTION OF THE SEVERAL VIEWS OF THE DRAWINGS

FIG. 1A is a diagram illustrating an example of operation in a first mode in an example configuration of a differential power amplifier according to an embodiment;

FIG. 1B is a diagram illustrating an example of operation in a second mode in the example configuration of the differential power amplifier according to the embodiment;

FIG. 2A is a diagram illustrating a filter circuit in the first mode;

FIG. 2B is a diagram illustrating the filter circuit in the second mode;

FIG. 3A is a graph illustrating an example of simulation results of frequency-gain characteristics in the first mode of the differential power amplifier according to the embodiment; and

FIG. 3B is a graph illustrating an example of simulation results of frequency-gain characteristics in the second mode of the differential power amplifier according to the embodiment.

### DETAILED DESCRIPTION OF THE DISCLOSURE

A differential power amplifier according to an embodiment will be described in detail below with reference to the drawings. Note that the present disclosure is not to be limited by this embodiment. Furthermore, components in embodiments include components that can be easily replaced by a person skilled in the art or substantially the same components. Each embodiment is illustrative, and configurations described in different embodiments can be partially replaced or combined. In Embodiment 2 and subsequent embodiments, a description of things in common with Embodiment 1 is omitted, and only respects in which Embodiment 2 and the subsequent embodiments differ from Embodiment 1 will be described. In particular, similar function effects achieved by similar configurations are not repeatedly described in each embodiment.

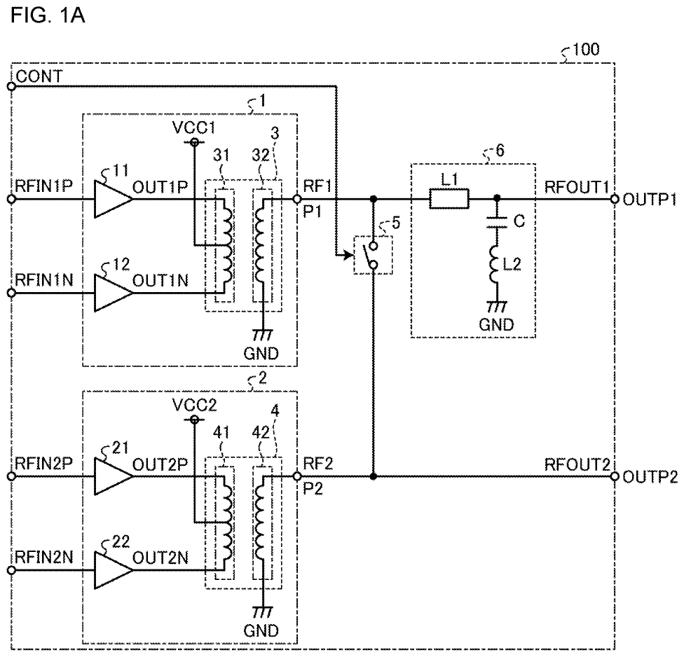

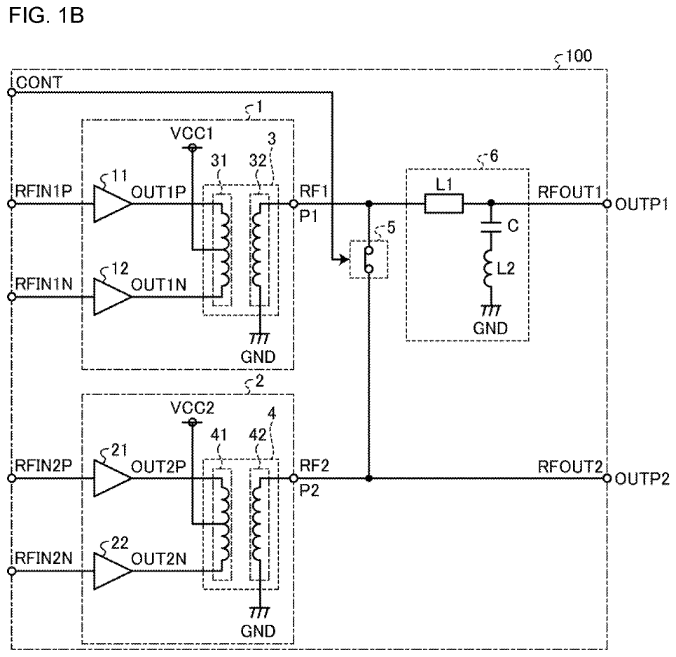

FIG. 1A is a diagram illustrating an example of operation in a first mode in an example configuration of a differential power amplifier according to an embodiment. FIG. 1B is a diagram illustrating an example of operation in a second mode in the example configuration of the differential power amplifier according to the embodiment. As illustrated in FIGS. 1A and 1B, a differential power amplifier 100 according to Embodiment 1 includes a first differential amplifier circuit 1, a second differential amplifier circuit 2, a switch circuit 5, and a filter circuit 6.

The first mode in the differential power amplifier 100 according to the embodiment is an efficiency-oriented mode in which a signal in a frequency band defined, for example, in the fifth generation mobile communication system (5G) is a signal to be amplified. In the first mode, the first differential amplifier circuit 1 performs amplification operation, and the second differential amplifier circuit 2 does not perform amplification operation. Note that an input signal in the first mode is not limited to that in the 5G and may also be a signal in a frequency band defined in the fourth generation mobile communication system (4G) or the sixth generation mobile communication system (6G).

The second mode in the differential power amplifier 100 according to the embodiment is an output power-oriented mode in which a signal in a frequency band defined, for example, in the second generation mobile communication system (2G) is a signal to be amplified. In the second mode, both the first differential amplifier circuit 1 and the second differential amplifier circuit 2 perform amplification operation.

In the present disclosure, an output signal RFOUT1 in the first mode is outputted from a first output terminal OUTP1. Furthermore, in the present disclosure, an output signal RFOUT2 in the second mode is outputted from a second output terminal OUTP2.

The first differential amplifier circuit 1 includes two amplifiers 11 and 12 that amplify a first differential signal, and a first balun transformer 3. The amplifier 11 amplifies an input signal RFIN1P. The amplifier 12 amplifies an input signal RFIN1N.

The second differential amplifier circuit 2 includes two amplifiers 21 and 22 that amplify a second differential signal, and a second balun transformer 4. The amplifier 21 amplifies an input signal RFIN2P. The amplifier 22 amplifies an input signal RFIN2N.

The amplifiers 11, 12, 21, and 22 may be constituted, for example, by a bipolar transistor or, for example, by a field-effect transistor (FET). When the amplifiers 11, 12, 21, and 22 are constituted by a bipolar transistor, a heterojunction bipolar transistor (HBT) is given as an example. The present disclosure is not limited by the configurations of the amplifiers 11, 12, 21, and 22.

The first balun transformer 3 includes an input-side winding 31 and an output-side winding 32.

The input-side winding 31 is connected between an output OUT1P and an output OUT1N of the first differential amplifier circuit 1. At a midpoint of the input-side winding 31, a center tap is provided, and a power-supply voltage VCC1 is applied to this center tap.

The input-side winding 31 and the output-side winding 32 of the first balun transformer 3 are coupled via an electromagnetic field. Thus, balanced output signals OUT1P and OUT1N outputted from the amplifiers 11 and 12 of the first differential amplifier circuit 1 are subjected to balanced-to-unbalanced conversion by the first balun transformer 3 and are outputted from an output terminal P1 as a first unbalanced signal RF1.

The second balun transformer 4 includes an input-side winding 41 and an output-side winding 42.

The input-side winding 41 is connected between an output OUT2P and an output OUT2N of the second differential amplifier circuit 2. At a midpoint of the input-side winding 41, a center tap is provided, and a power-supply voltage VCC2 is applied to this center tap.

The input-side winding 41 and the output-side winding 42 of the second balun transformer 4 are coupled via an electromagnetic field. Thus, balanced output signals OUT2P and OUT2N outputted from the amplifiers 21 and 22 of the second differential amplifier circuit 2 are subjected to balanced-to-unbalanced conversion by the second balun transformer 4 and are outputted from an output terminal P2 as a second unbalanced signal RF2.

In the examples illustrated in FIGS. 1A and 1B, the switch circuit 5 is, for example, a one-to-one connection multiplexer and is provided between the output terminal P1 of the first differential amplifier circuit 1 and the output terminal P2 of the second differential amplifier circuit 2. The switch circuit 5 is controlled to an ON or OFF state in accordance with a mode control signal CONT inputted from an external control circuit (not illustrated). The configuration of the switch circuit 5 illustrated in FIGS. 1A and 1B is an example, and the present disclosure is not limited by the configuration of the switch circuit 5.

The filter circuit 6 includes a capacitor C, a first inductor L1, and a second inductor L2. The first inductor L1 has one end connected to the output terminal P1 of the first differential amplifier circuit 1, and the other end connected to the first output terminal OUTP1. The capacitor C and the second inductor L2 are connected in series between the first output terminal OUTP1 and a ground potential GND.

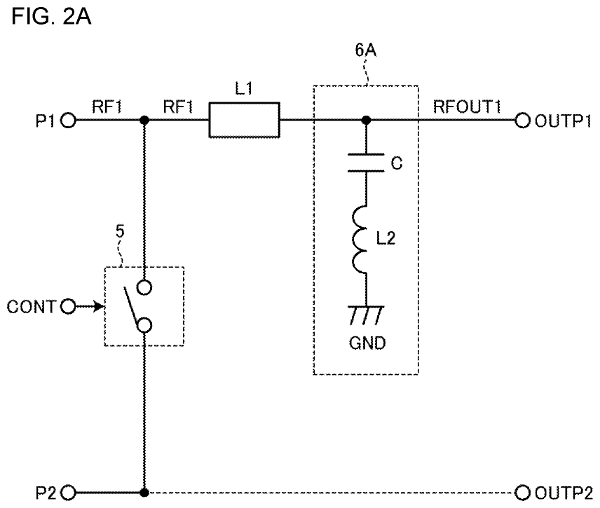

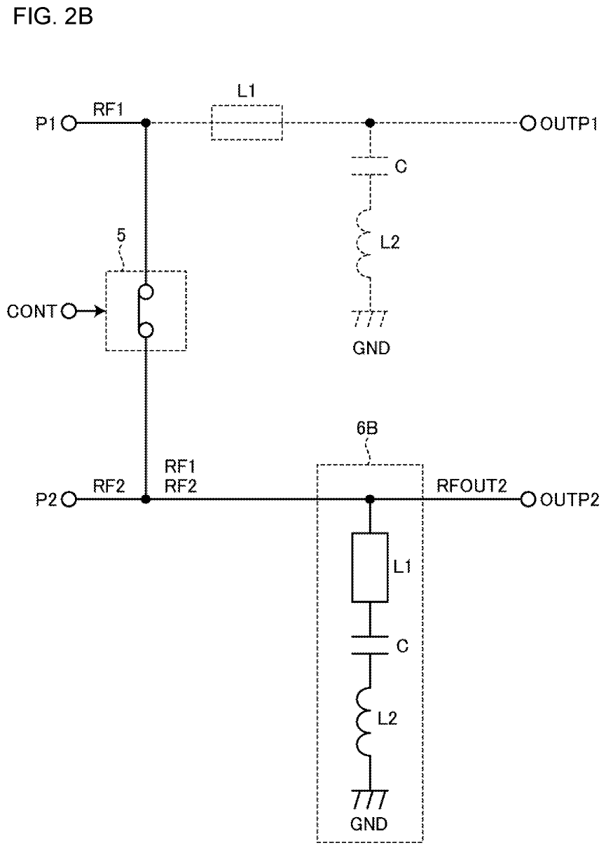

FIG. 2A is a diagram illustrating the filter circuit in the first mode. FIG. 2B is a diagram illustrating the filter circuit in the second mode.

In the differential power amplifier 100 according to the embodiment, as illustrated in FIGS. 1A and 2A, the switch circuit 5 is controlled to an OFF state in the first mode, disconnecting the output terminal P1 of the first differential amplifier circuit 1 and the output terminal P2 of the second differential amplifier circuit 2. Thus, as illustrated in FIG. 2A, a first notch filter 6A is constituted by the capacitor C and the second inductor L2.

Furthermore, as illustrated in FIGS. 1B and 2B, the switch circuit 5 is controlled to an ON state in the second mode, connecting the output terminal P1 of the first differential amplifier circuit 1 and the output terminal P2 of the second differential amplifier circuit 2. In FIG. 2B, actual dispositions of the capacitor C, the first inductor L1, and the second inductor L2 are indicated by the dashed lines. When the switch circuit 5 is controlled to an ON state in the second mode, the capacitor C, the first inductor L1, and the second inductor L2 can be considered to equivalently constitute a second notch filter circuit 6B indicated by the solid lines in FIG. 2B between the output terminals P1 and P2 of the first and second differential amplifier circuits 1 and 2 and the first output terminal OUTP1.

In the present disclosure, the first inductor L1 is constituted by a wiring inductance component between the output terminal P1 of the first differential amplifier circuit 1 and the first notch filter 6A. The first inductor L1, which is a wiring inductor component, is viewed differently in the first notch filter 6A and the second notch filter 6B.

Specifically, as illustrated in FIG. 1A, in the first mode, the first inductor L1 is a wiring inductance component present on a path of the first unbalanced signal RF1 between the output terminal P1 of the first differential amplifier circuit 1 and the first notch filter 6A and is not included in the first notch filter 6A.

On the other hand, as illustrated in FIG. 2B, in the second mode, the first inductor L1 is included in the second notch filter 6B formed between a path of a combined signal of the first unbalanced signal RF1 and the second unbalanced signal RF2 that are made equal in potential by controlling the switch circuit 5 to an ON state and the ground potential GND.

Thus, the first inductor L1 constituted by the wiring inductance component between the output terminal P1 of the first differential amplifier circuit 1 and the first notch filter 6A is not included in the first notch filter 6A in the first mode and is included in the second notch filter 6B in the second mode. Consequently, frequencies of attenuation poles of the first notch filter 6A in the first mode and the second notch filter 6B in the second mode differ.

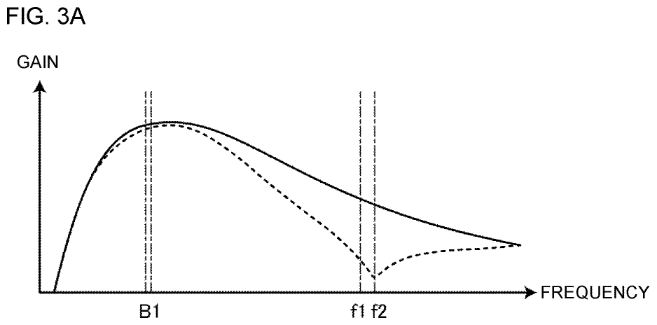

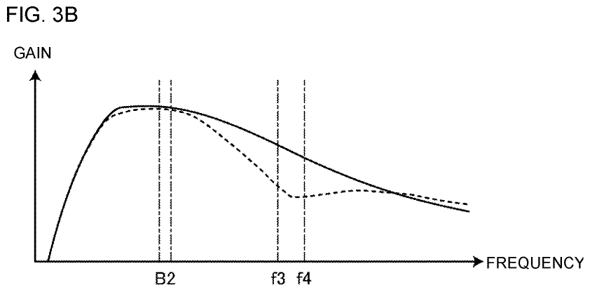

FIG. 3A is a graph illustrating an example of simulation results of frequency-gain characteristics in the first mode of the differential power amplifier according to the embodiment. FIG. 3B is a graph illustrating an example of simulation results of frequency-gain characteristics in the second mode of the differential power amplifier according to the embodiment. In the examples illustrated in FIGS. 3A and 3B, the solid lines indicate simulation results of frequency-gain characteristics in the respective modes of the differential power amplifier according to the embodiment in which the filter circuit 6 is provided. The dashed lines indicate simulation results of frequency-gain characteristics in the respective modes in a case where no filter circuit 6 is provided.

In the configuration of the differential power amplifier 100 according to the embodiment, setting the capacitor C, the first inductor L1, and the second inductor L2 appropriately can effectively attenuate a specified harmonic component of a frequency band in each mode. This can optimize characteristics of the output signals RFOUT1 and RFOUT2 in the respective modes.

Specifically, for example, the capacitor C, the first inductor L1, and the second inductor L2 can be set appropriately so that a resonant frequency of the first notch filter 6A falls within a specified frequency range f1-f2 including an nth harmonic component (where n≥3) of a fundamental wave in a frequency band B1 in the first mode and so that a resonant frequency of the second notch filter 6B falls within a specified frequency range f2-f2 including an (n-m)th harmonic component (where n>m≥1, n-m ≥2) of a fundamental wave in a frequency band B2 in the second mode.

More specifically, for example, as illustrated in FIG. 3A, the resonant frequency of the first notch filter 6A can be set to fall within the specified frequency range f1-f2 including a frequency corresponding to a third harmonic of the fundamental wave in the frequency band B1 in the first mode, and, as illustrated in FIG. 3B, the resonant frequency of the second notch filter 6B can be set to fall within the specified frequency range f3-f4 including a frequency corresponding to a second harmonic of the fundamental wave in the frequency band B2 in the second mode.

Thus, in the configuration of the differential power amplifier 100 according to the embodiment, as described above, appropriately setting the capacitor C, the first inductor L1, and the second inductor L2 that constitute the filter circuit 6 can determine both the resonant frequency of the first notch filter 6A in the first mode and the resonant frequency of the second notch filter 6B in the second mode.

Furthermore, the capacitor C and the second inductor L2 can be shared by both the first notch filter 6A in the first mode and the second notch filter 6B in the second mode.

This can optimize bandpass characteristics for each of the frequency bands corresponding to the first mode and the second mode without provision of filter circuits for a signal to be amplified in the first mode (for example, a signal in a frequency band defined in 5G) and a signal to be amplified in the second mode (for example, a signal in a frequency band defined in 2G) and can contribute miniaturization of the differential power amplifier 100.

Furthermore, the first inductor L1 is constituted by the wiring inductance component between the output terminal P1 of the first differential amplifier circuit 1 and the first notch filter 6A, thereby enabling further miniaturization of the differential power amplifier 100.

Note that the above-described embodiment is intended to facilitate understanding of the present disclosure but is not intended for a limited interpretation of the present disclosure. The present disclosure can be changed or improved without departing from the gist thereof and also encompasses equivalents thereof.

What is claimed is:

1. A differential power amplifier comprising:
a plurality of differential amplifier circuits including a first differential amplifier circuit and a second differential amplifier circuit;
a first inductor having a first end connected to an output terminal of the first differential amplifier circuit;
a first output terminal connected to a second end of the first inductor;
a capacitor and a second inductor connected in series between the first output terminal and a ground potential;
a second output terminal connected to an output terminal of the second differential amplifier circuit; and
a switch circuit between the output terminal of the first differential amplifier circuit and the output terminal of the second differential amplifier circuit,
wherein the differential power amplifier is configured to operate in:
a first mode in which the first differential amplifier circuit is configured to perform an amplification operation and the second differential amplifier circuit is configured to not perform the amplification operation, and
a second mode in which both the first differential amplifier circuit and the second differential amplifier circuit are configured to perform the amplification operation, and
wherein the switch circuit is in an OFF state in the first mode, and is in an ON state in the second mode.

2. The differential power amplifier according to claim 1,
wherein the capacitor and the second inductor constitute a first notch filter in the first mode, and
wherein the capacitor, the first inductor, and the second inductor constitute a second notch filter in the second mode.

3. The differential power amplifier according to claim 2, wherein, in the first mode, a resonant frequency of the first notch filter is in a frequency range including a frequency corresponding to an nth harmonic (where n≥3) of a fundamental wave of a signal amplified by the differential power amplifier.

4. The differential power amplifier according to claim 2, wherein, in the second mode, a resonant frequency of the second notch filter is in a frequency range including a frequency corresponding to an (n-m)th harmonic (where n>m ≥1, n-m≥2) of a fundamental wave of a signal amplified by the differential power amplifier.

5. The differential power amplifier according to claim 3, wherein, in the second mode, a resonant frequency of the second notch filter is in a frequency range including a frequency corresponding to an (n-m)th harmonic (where n>m≥1, n-m≥2) of the fundamental wave of the signal amplified by the differential power amplifier.

6. The differential power amplifier according to claim 2, wherein the first inductor is a wiring inductance component between the output terminal of the first differential amplifier circuit and the first notch filter.

7. The differential power amplifier according to claim 3, wherein the first inductor is a wiring inductance component between the output terminal of the first differential amplifier circuit and the first notch filter.

8. The differential power amplifier according to claim 4, wherein the first inductor is a wiring inductance component between the output terminal of the first differential amplifier circuit and the first notch filter.

9. The differential power amplifier according to claim 5, wherein the first inductor is a wiring inductance component between the output terminal of the first differential amplifier circuit and the first notch filter.
